(19) United States
(12) Patent Application Publication
(10) Pub. No.: US 2026/0356581 A1
(43) Pub. Date: Nov. 12, 2026

(54) TRANSFER MACHINE

(71) Applicant: DAIFUKU CO., LTD., Osaka-shi (JP)

(72) Inventor: Kazuya OMORI, Shiga (JP)

(73) Assignee: DAIFUKU CO., LTD., Osaka-shi (JP)

(21) Appl. No.: 19/631,316

(22) Filed: Mar. 27, 2026

(30) Foreign Application Priority Data
May 9, 2025 (JP) 2025-078934

(51) Int. Cl. B65G 1/04; H10P 72/30

(52) U.S. Cl. CPC B65G 1/0435; H10P 72/3404; B65G 2201/0297

(57) ABSTRACT

A transfer machine includes: a base; a pivoting unit; and an electrical wire, wherein one of the base and the pivoting unit is provided with an outer circumferential surface extending substantially along a circumferential direction of a pivot axis, the other of the base and the pivoting unit is provided with an inner circumferential surface, the electrical wire includes: a first section; a second section; and a third section curved in a state protruding to one side in the circumferential direction between the first section and the second section, and the third section performs relative movement with respect to the base in the circumferential direction in a range located farther from the pivot axis compared to the outer circumferential surface and closer to the pivot axis compared to the inner circumferential surface, accompanying the pivoting of the pivoting unit about the pivot axis with respect to the base.

### CROSS-REFERENCE TO RELATED APPLICATION(S)

The present application claims priority to and incorporates by reference the entire contents of Japanese Patent Application No. 2025-078934 filed in Japan on May 9, 2025.

### BACKGROUND

### 1. Field

The present disclosure relates to a transfer machine.

### 2. Related Art

There has been a conventionally known conveyance device including: a mast extending in an up-down direction; and a transfer machine that moves in the up-down direction along the mast (refer to JP 2003-205488 A, for example). In JP 2003-205488 A, the transfer machine includes a base and a pivoting body pivotably supported by the base. The pivoting body includes a transfer mechanism that transfers articles.

In such a transfer machine, the pivoting body usually includes electrical components such as: a motor that electrically drives the transfer mechanism; and various sensors. For the operation of the electrical component, an electrical wire is routed between the base and the pivoting unit. The electrical wire performs, at least partially, relative movement with respect to the base accompanying the pivoting of the pivoting unit with respect to the base.

In the configuration in which the electrical wire performs relative movement with respect to the base, if the movement range of the electrical wire in the base changes from the initially assumed range with deterioration of the electrical wire due to long-term use, etc., for example, the moving electrical wire might interfere with a component, etc. provided in the base. In this case, there is a possibility of occurrence of hindrance on the pivoting of the pivoting unit, or occurrence of damage to the electrical wire, for example.

There is a need for a transfer machine capable of suppressing occurrence of an inconvenient event accompanying movement of an electrical wire, for example.

### SUMMARY

In some embodiments, a transfer machine includes: a base; a pivoting unit including a transfer mechanism configured to transfer an article and an electrical component, the pivoting unit being pivotably supported about a pivot axis with respect to the base; and an electrical wire having a conductive wire electrically connected to the electrical component, the electrical wire being fixed to the base and the pivoting unit, wherein one of the base and the pivoting unit is provided with an outer circumferential surface extending substantially along a circumferential direction of the pivot axis, the other of the base and the pivoting unit is provided with an inner circumferential surface extending substantially along the circumferential direction, the electrical wire includes: a first section extending substantially along the outer circumferential surface; a second section extending substantially along the inner circumferential surface; and a third section that is curved in a state protruding to one side in the circumferential direction between the first section and the second section, and the third section performs relative movement with respect to the base in the circumferential direction in a first range located farther from the pivot axis compared to the outer circumferential surface and closer to the pivot axis compared to the inner circumferential surface, accompanying the pivoting of the pivoting unit about the pivot axis with respect to the base.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary and schematic side view of a conveyance device including a transfer machine of an embodiment;

FIG. 2 is an exemplary and schematic side view of the transfer machine of the embodiment;

FIG. 3 is an exemplary and schematic side view of the transfer machine of the embodiment, being a diagram illustrating a state in which a relative angle of a pivoting unit with respect to a base about a pivot axis is different from the relative angle in FIG. 2;

FIG. 4 is an exemplary plan view schematically illustrating a base, a pivoting unit, and an electrical wire included in the transfer machine of the embodiment, being a view in a state of FIG. 2;

FIG. 5 is an exemplary plan view schematically illustrating the base, the pivoting unit, and the electrical wire included in the transfer machine of the embodiment, being a view in a state between FIG. 2 and FIG. 3;

FIG. 6 is an exemplary plan view schematically illustrating the base, the pivoting unit, and the electrical wire included in the transfer machine of the embodiment, being a view in a state of FIG. 3;

FIG. 7 is an exemplary and schematic perspective view of a part of the transfer machine of the embodiment, being a view in the state of FIG. 4; and

FIG. 8 is an exemplary and schematic perspective view of a part of the transfer machine of the embodiment, being a view in the state of FIG. 6.

### DETAILED DESCRIPTION

Hereinafter, exemplary embodiments of the present disclosure are disclosed. The configurations of the embodiments described below and the actions and results (effects) obtained from the configurations are described as one example. The present disclosure can also be implemented by configurations other than those disclosed in the following embodiments. In addition, according to the present disclosure, it is possible to obtain at least one of various effects (including derivative effects) obtained by the following configurations.

In the present specification, ordinal numbers can be given for convenience to distinguish directions, components, positions, portions, mechanisms, members, etc. The ordinal number does not necessarily indicate the priority or order, and does not specify the number.

Each drawing includes illustrations of arrows indicating directions. The X direction, the Y direction, and the Z direction intersect with each other and are substantially orthogonal to each other. The Z direction is substantially along a vertically upward direction and can also be denoted as an upward direction, while a direction opposite to the Z direction can also be denoted as a downward direction. The X direction and the Y direction intersect with the up-down direction and are substantially along the horizontal direction. The X direction and the Y direction can also be denoted as lateral directions.

### Conveyance Device and Storage Shelf

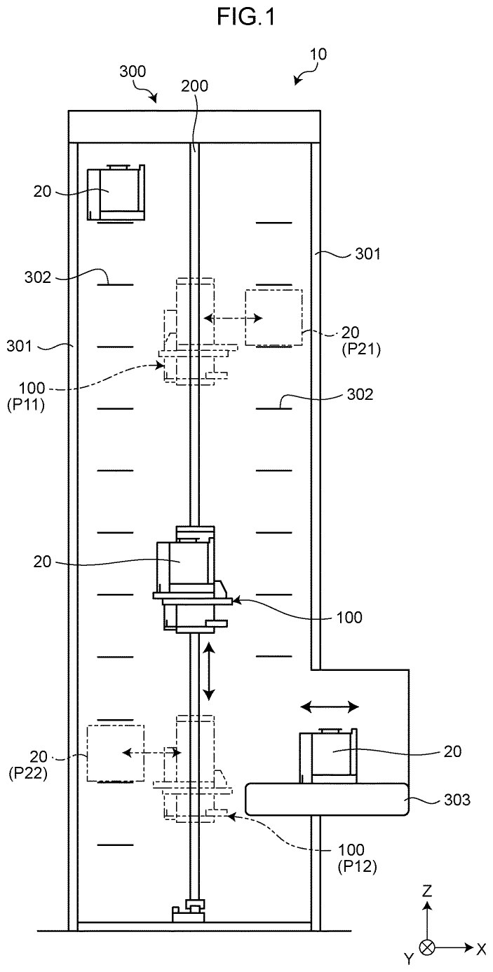

FIG. 1 is a side view of a conveyance device 10 and a storage shelf 300. The conveyance device 10 includes: a mast 200 extending in the up-down direction; and a transfer machine 100 supported by the mast 200 so as to be movable in the up-down direction. The transfer machine 100 is configured to be stoppable at a plurality of positions in the Z direction. The transfer machine 100 can move while supporting a storage container 20 that stores articles. The article stored in the storage container 20 includes, but is not limited to, a semiconductor wafer, a circuit board, an electronic component, for example. The storage container 20 can also be denoted as an object to be conveyed. In addition, the storage container 20 itself can also be denoted as an article.

In addition, in a lower portion of the mast 200, there is provided a truck cart (not illustrated) capable of moving the mast 200 in the Y direction and a direction opposite to the Y direction. The truck cart is configured to be stoppable at a plurality of positions in the Y direction.

The storage shelf 300 is provided so as to be adjacent to the conveyance device 10 in the X direction and a direction opposite to the X direction. The storage shelf 300 each includes: a support column 301 extending in the Z direction; and a shelf member 302 provided in plurality and fixed to the support column 301. The shelf member 302 is provided at predetermined intervals in the Z direction, and can each support the storage container 20. The space on the upper side of the shelf member 302 is a space for accommodating the storage container 20. The spaces accommodating the storage containers 20 are arranged in a matrix when viewed in the X direction.

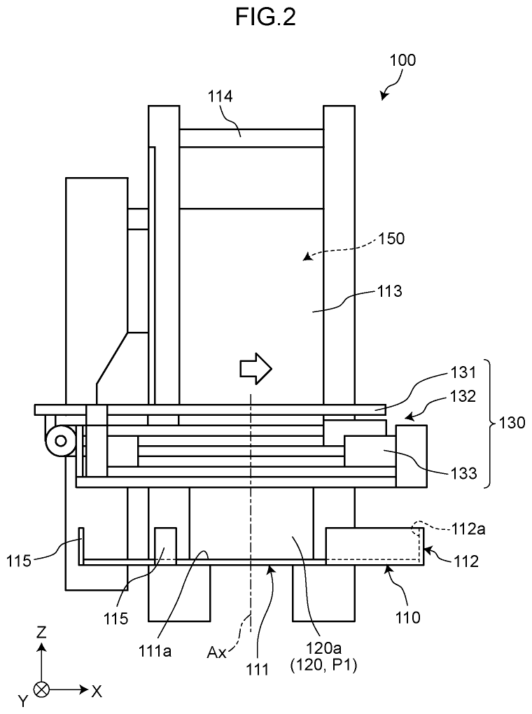

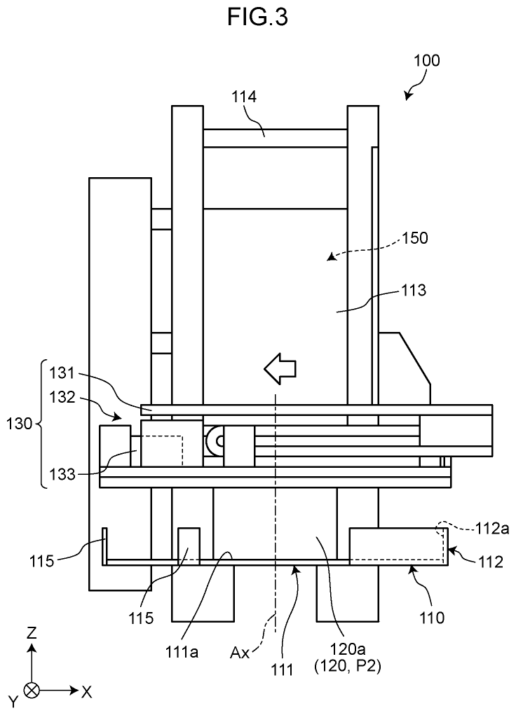

In such a configuration, the transfer machine 100 can be located at a position (for example, P11 and P12 in FIG. 1) adjacent to each of the storage positions (for example, P21 and P22 in FIG. 1) of the shelf members 302 in the X direction or the opposite direction of the X direction. The transfer machine 100 includes a transfer mechanism 130 (refer to FIGS. 2 and 3, etc. to be described below) capable of transferring the storage container 20 to and from the shelf member 302. The transfer machine 100 is located at positions (P11 and P12) each facing storage positions (P21 and P22), and can carry the storage container 20 into the storage positions (P21 and P22) or carry the storage container 20 out of the storage positions (P21 and P22) using the transfer mechanism 130.

### Transfer Machine

FIG. 2 is a side view of the transfer machine 100, and FIG. 3 is a side view illustrating another state of the transfer machine 100. As illustrated in FIGS. 2 and 3, the transfer machine 100 includes a base 110, a pivoting unit 120, and a transfer mechanism 130.

The base 110 is movably supported by the mast 200 (refer to FIG. 1) via a moving mechanism 150 including rollers, etc. The base 110 includes a bottom plate 111, a guide plate 112, a side plate 113, a top plate 114, a guide rib 115, etc.

The bottom plate 111 intersects with and is substantially orthogonal to the Z direction. An upper surface 111a of the bottom plate 111 faces the Z direction, and intersects with and is substantially orthogonal to the Z direction.

The guide plate 112 extends in an arc shape substantially in a circumferential direction of the pivot axis Ax of the pivoting unit 120 (hereinafter, simply denoted as a circumferential direction) at a substantially constant height in the Z direction, and partially forms a cylindrical shape. An axial direction of the pivot axis Ax of the pivoting unit 120 (hereinafter, simply denoted as an axial direction) extends substantially in the Z direction. An inner circumferential surface 112a of the guide plate 112 faces the inner side in a radial direction of the pivot axis Ax (hereinafter, simply denoted as a radial direction) and extends substantially in the circumferential direction to form a cylindrical inner surface shape.

The side plate 113 and the top plate 114 have a function of protecting a side portion and an upper portion of the storage container 20 held by the transfer mechanism 130 of the transfer machine 100, and a function of supporting the moving mechanism 150, electrical components such as a sensor, etc.

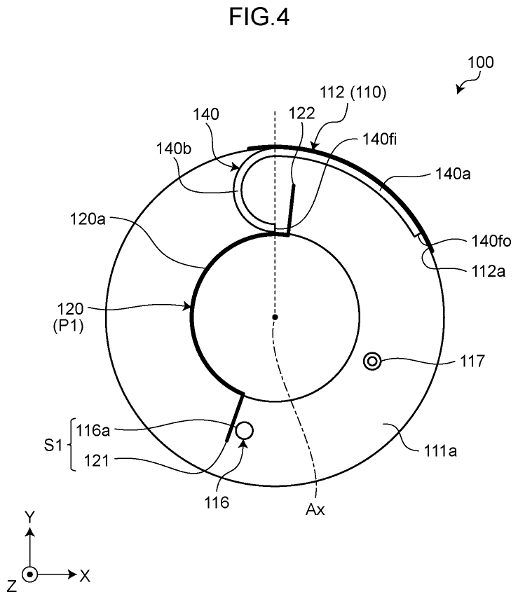

The guide rib 115 can securely hold an electrical wire 140 to be described below (refer to FIGS. 4 to 6) in a predetermined routing path via a holding tool such as a binding band, for example.

The pivoting unit 120 is supported by the base 110 so as to be pivotable about the pivot axis Ax. The pivoting unit 120 includes an outer circumferential surface 120a. The outer circumferential surface 120a faces the outer side in the radial direction, extends substantially in the circumferential direction at a substantially constant height in the Z direction, and forms a partial cylindrical outer surface shape.

The pivoting unit 120 can pivot about the pivot axis Ax by operation of an electric motor (not illustrated), etc. provided on the base 110. In the present embodiment, the pivoting unit 120 can perform relative pivoting with respect to the base 110, for example, between a posture P1 illustrated in FIG. 2 and a posture P2 illustrated in FIG. 3. Hereinafter, the relative pivoting of the pivoting unit 120 with respect to the base 110 is simply denoted as pivoting.

The transfer mechanism 130 is attached to the pivoting unit 120. The transfer mechanism 130 includes a support unit 131, an operation unit 132, and a drive source 133. The support unit 131 supports the storage container 20. The operation unit 132 operates in each of the postures P1 and P2 of the pivoting unit 120 in FIGS. 2 and 3 to change the position of the support unit 131 at least in the X direction. The drive source 133 is a drive source of the operation unit 132, and is an electrical component such as an electric motor, for example. When the drive source 133 is an electric motor, the operation unit 132 includes a motion conversion mechanism that converts rotation of an output unit such as a shaft of the electric motor into linear motion of the support unit 131, for example.

In the present embodiment, in the posture P1 of the pivoting unit 120 illustrated in FIG. 2, the support unit 131, that is, the storage container 20 moves between the position illustrated in FIG. 2 and the position separated from the position in the X direction in accordance with the operation (expansion and contraction) of the operation unit 132 corresponding to the operation of the drive source 133. A posture P1 in FIG. 2 is, for example, a posture when the storage container 20 is transferred to and from the storage position (P21) on the right side in FIG. 1.

In addition, in the present embodiment, in the posture P2 of the pivoting unit 120 illustrated in FIG. 3, the support unit 131, that is, the storage container 20 moves between the position illustrated in FIG. 3 and the position separated from the position in the direction opposite to the X direction in accordance with the operation (expansion and contraction) of the operation unit 132 corresponding to the operation of the drive source 133. The posture P2 in FIG. 3 is, for example, a posture when the storage container 20 is transferred to and from the storage position (P22) on the left side in FIG. 1.

### Pivoting of Pivoting Unit

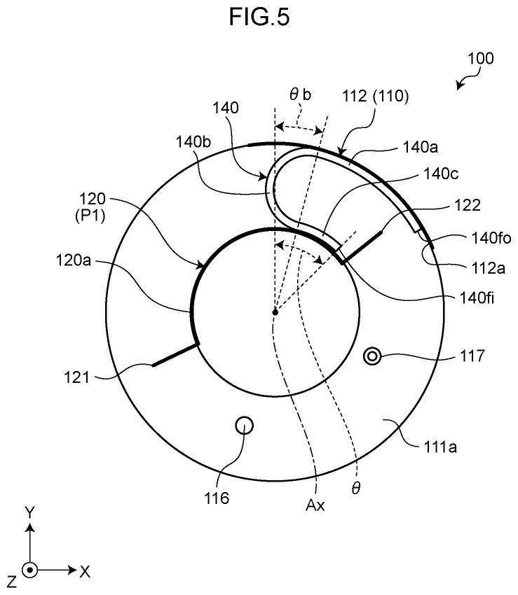

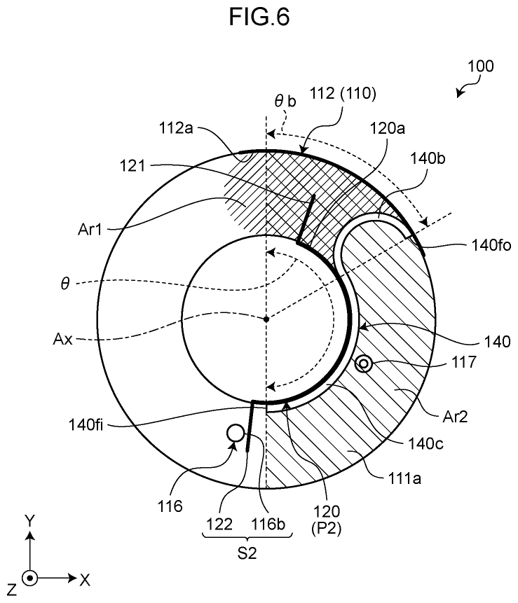

FIGS. 4 to 6 are plan views illustrating changes in the shape of the electrical wire 140 corresponding to the pivoting of the pivoting unit 120. FIG. 4 illustrates a state in which the pivoting unit 120 is in the posture P1, FIG. 6 illustrates a state in which the pivoting unit 120 is in the posture P2, and FIG. 5 illustrates a state in which the pivoting unit 120 is in a posture between the posture P1 and the posture P2. Each of FIGS. 4 to 6 is a schematic view for illustrating the concept and operation, and does not necessarily match the actual shape and scale. In the following description, the pivoting direction of the pivoting unit 120 about the pivot axis Ax is a clockwise direction and a counterclockwise direction in plan view when viewed from the line of sight of FIGS. 4 to 6, that is, in a direction opposite to the Z direction.

In the present embodiment, as an example, the pivoting unit 120 pivots in the clockwise direction from the posture P1 (FIG. 4) to the posture P2 (FIG. 6), and pivots in the counterclockwise direction from the posture P2 to the posture P1. However, the configuration is not limited to this configuration, and the pivoting unit 120 may pivot in the counterclockwise direction from the posture P1 to the posture P2, and may pivot in the clockwise direction from the posture P2 to the posture P1.

### Stopper Mechanism

A first stopper mechanism S1 (FIG. 4) and a second stopper mechanism S2 (FIG. 6) individually suppress excessive pivoting of the pivoting unit 120 with respect to the base 110.

As illustrated in FIG. 4, the first stopper mechanism S1 includes an abutting portion 121 and an abutted portion 116a. The abutted portion 116a is an end of a stopper member 116 in the clockwise direction, and is in contact with the abutting portion 121 or faces the abutting portion 121 with a gap in the counterclockwise direction in the state of FIG. 4. With this configuration of the first stopper mechanism S1, the abutting portion 121, that is, the pivoting unit 120 is restricted from pivoting in the counterclockwise direction beyond the position of abutting on the abutted portion 116a. The abutting portion 121 is an example of a first abutting portion, while the abutted portion 116a is an example of a first abutted portion.

As illustrated in FIG. 6, the second stopper mechanism S2 includes an abutting portion 122 and an abutted portion 116b. The abutted portion 116b is an end of the stopper member 116 in the counterclockwise direction, and is in contact with the abutting portion 122 or faces the abutting portion 122 with a gap in the clockwise direction in the state of FIG. 6. With this configuration of the second stopper mechanism S2, the abutting portion 122, that is, the pivoting unit 120 is restricted from pivoting in the clockwise direction beyond the position of abutting on the abutted portion 116b. The abutting portion 122 is an example of a second abutting portion, while the abutted portion 116b is an example of a second abutted portion.

Specifically, the stopper member 116 has a pillar shape protruding in the Z direction from the upper surface 111a of the bottom plate 111 of the base 110, for example, but is not limited to this configuration. The abutting portions 121 and 122 are each configured as, for example, an arm-shaped member protruding outward in the radial direction from the outer circumferential surface 120a of the pivoting unit 120, but are not limited to this configuration. For example, the abutting portions 121 and 122 may each be a part of a component provided on the pivoting unit 120, a part of the cover of the component, etc., or may be a protruding piece provided on the cover, etc.

As described above, the abutted portions 116a and 116b are both provided in the stopper member 116. According to this configuration, the number of components of the first stopper mechanism S1 and the second stopper mechanism S2 can be reduced compared to a case where the abutted portions 116a and 116b are separately provided, making it possible to obtain an advantage of suppressing manufacturing labor and cost.

### Movement of Electrical Wire Accompanying Pivoting of Pivoting Unit

The pivoting unit 120 includes electrical components such as an electric motor that functions as the drive source 133, and various sensors (not illustrated), for example. The electrical wire 140 is routed between the base 110 and the pivoting unit 120 in order to supply power to the electrical component or exchange signals with the electrical component. As described above, the pivoting unit 120 pivots with respect to the base 110. Therefore, a fixing position 140fi of the electrical wire 140 in the pivoting unit 120 pivots with respect to the base 110 in accordance with the pivoting, and accordingly, at least a part of the section of the electrical wire 140 performs relative movement with respect to the base 110. In the present embodiment, in order to ensure smooth relative movement with respect to the base 110, the electrical wire 140 is placed on the substantially flat upper surface 111a of the bottom plate 111. That is, the electrical wire 140 moves while sliding substantially along the upper surface 111a at least partially.

The electrical wire 140 is fixed to the base 110 at a fixing position 140fo, and is fixed to the pivoting unit 120 at the fixing position 140fi. In the electrical wire 140, a section between the fixing position 140fo and the fixing position 140fi is a section that performs relative movement with respect to the base 110 and the pivoting unit 120 accompanying the pivoting of the pivoting unit 120. FIGS. 4 to 6 illustrate only a section of the electrical wire 140 that performs relative movement with respect to the base 110 and the pivoting unit 120, and illustrate no other fixing sections such as a section fixed to the guide rib 115, for example. In addition, in the present embodiment, the length of the electrical wire 140 between the two fixing positions 140fo and 140fi is unchanged (constant), and thus, is not changed by the pivoting of the pivoting unit 120.

The electrical wire 140 includes: a conductive wire electrically connected to a conductor of the electrical component; and an insulating sheath covering the conductor. The electrical wire 140 may have only one conductive wire, may have a plurality of conductors each covered with an insulating sheath, or may be a bundle of a plurality of electrical wires. With this configuration, the electrical wire 140 has elasticity.

The state of FIG. 4 is a state in which the pivoting unit 120 is in the posture P1, that is, a state in which the pivoting unit is located in the vicinity of a pivoting restriction position in the counterclockwise direction, and a state in which the pivoting unit has pivoted in the counterclockwise direction from the states of FIGS. 5 and 6. In the state of FIG. 4, the electrical wire 140 includes at least an outer section 140a and a bridge section 140b. The outer section 140a is substantially in contact with the inner circumferential surface 112a and extends in the circumferential direction substantially along the inner circumferential surface 112a between the fixing position 140fo and the bridge section 140b. The bridge section 140b is bridged between the inner circumferential surface 112a and the outer circumferential surface 120a. As described above, the electrical wire 140 has appropriate elasticity. Therefore, the electrical wire 140 is gently curved in a state of protruding in the counterclockwise direction in a semicircular shape having a diameter being a difference in radius between the inner circumferential surface 112a and the outer circumferential surface 120a, for example, without being sharply bent in the bridge section 140b. The counterclockwise direction is a direction opposite to the outer section 140a with respect to the end of the bridge section 140b on the outer side in the radial direction, that is, the end on the inner circumferential surface 112a side in the circumferential direction. The outer section 140a is an example of a second section, and the bridge section 140b is an example of a third section. In the state of FIG. 4, the electrical wire 140 may include an inner section 140c which is relatively short and extends substantially along the outer circumferential surface 120a (refer to FIGS. 5 and 6).

The state of FIG. 5 is a state in which the pivoting unit 120 is in the posture P1. This state is a state in which the pivoting unit 120 has pivoted in the clockwise direction from the state of FIG. 4, and is also a state in which the pivoting unit has pivoted in the counterclockwise direction from the state of FIG. 6.

When the pivoting unit 120 has pivoted in the clockwise direction from the state of FIG. 4 to the state of FIG. 5, the length of the inner section 140c of the electrical wire 140 gradually increases with the pivoting of the fixing position 140fi of the electrical wire 140 in the clockwise direction with respect to the pivoting unit 120. The inner section 140c is substantially in contact with the outer circumferential surface 120a and extends in the circumferential direction substantially along the outer circumferential surface 120a between the fixing position 140fi and the bridge section 140b. Here, as described above, the length of the electrical wire 140 is constant with no change. Accordingly, as the inner section 140c becomes longer with the pivoting of the pivoting unit 120, the length of the outer section 140a becomes shorter. In addition, the intermediate portion, namely, the bridge section 140b moves in the clockwise direction during this time. Similarly to the state of FIG. 4, the bridge section 140b maintains a curved state protruding in the counterclockwise direction at each position during movement. The counterclockwise direction is a direction opposite to the inner section 140c with respect to the end of the bridge section 140b on the inner side in the radial direction, that is, the end on the outer circumferential surface 120a side in the circumferential direction. The inner section 140c is an example of a first section.

On the other hand, when the pivoting unit 120 has pivoted in the counterclockwise direction from the state of FIG. 6 to the state of FIG. 5, the length of the inner section 140c gradually decreases and the length of the outer section 140a gradually increases with the pivoting of the fixing position 140fi in the counterclockwise direction. In addition, the intermediate portion, namely, the bridge section 140b moves in the counterclockwise direction during this time. Also in this case, similarly to the state of FIG. 4, the bridge section 140b maintains a protruding curved state in the counterclockwise direction at each position during movement.

The state of FIG. 6 is a state in which the pivoting unit 120 is in the posture P2, that is, a state in which the pivoting unit is located in the vicinity of a pivoting restriction position in the clockwise direction, and a state in which the pivoting unit 120 has pivoted in the clockwise direction from the states of FIGS. 4 and 5. In the state of FIG. 6, the electrical wire 140 includes at least the inner section 140c and the bridge section 140b. Even in the state of FIG. 6, the bridge section 140b maintains a curved state protruding in the counterclockwise direction as in the states of FIGS. 4 and 5. In the state of FIG. 6, the electrical wire 140 may have a relatively short outer section 140a substantially along the inner circumferential surface 112a.

As described above, the electrical wire 140 has elasticity. For this reason, the bridge section 140b curved between the outer circumferential surface 120a and the inner circumferential surface 112a can apply elastic repulsive force, that is, pressing force to both the outer circumferential surface 120a and the inner circumferential surface 112a regardless of the position in the circumferential direction. Based on the pressing force, frictional force is generated between the electrical wire 140 and the inner circumferential surface 112a, maintaining the state in which the outer section 140a extends substantially along the inner circumferential surface 112a. In addition, based on the pressing force, frictional force is also generated between the electrical wire 140 and the outer circumferential surface 120a, maintaining the state in which the inner section 140c extends substantially along the outer circumferential surface 120a. Therefore, according to the present embodiment, in the pivoting of the pivoting unit 120 between the posture P1 and the posture P2, the bridge section 140b of the electrical wire 140 can move in the circumferential direction within a first range Ar1, being a range hatched diagonally upward to the right, in FIG. 6 in a state where the above-described curved state is maintained. The first range Ar1 is a part of a region located farther from the pivot axis Ax compared to the outer circumferential surface 120a and closer to the pivot axis Ax compared to the inner circumferential surface 112a.

Here, as illustrated in FIGS. 5 and 6, the pivoting angle of the fixing position 140fi (that is, the pivoting angle of the pivoting unit 120) is defined as θ (rad), and the pivoting angle of the bridge section 140b is defined as θb (rad). The radius of the outer circumferential surface 120a is defined as R1, and the radius of the inner circumferential surface 112a is defined as R2. In this case, in the pivoting of the pivoting unit 120 from the state of FIG. 4 to each state of FIGS. 5 and 6, the increment of the length of the inner section 140c is (θ−θb)×R1, and the decrement of the length of the outer section 140a is θb×(R2). As described above, the length of the electrical wire 140 between the fixing position 140fo and the fixing position 140fi is constant. Therefore, assuming that the semicircular curved shape of the bridge section 140b is unchanged, the increment of the length of the inner section 140c is equal to the decrement of the length of the outer section 140a. Accordingly, the following Formula (1) is established.

(θ−θb)×R1=θb×(R2) (1)

Based on Formula (1), the following Formula (2) is established.

Θb=R1/(R1+R2)×θ (2)

FIG. 6 illustrates a case where R2=2×R1 and θ=π (rad) (=180°). In this case, θb=⅓×π (rad) (=60°) is obtained from Formula (2). That is, even when the pivoting angle of the pivoting unit 120 is relatively wide such as 180°, it can be seen that the first range Ar1, which is the movement trace of the bridge section 140b, can be relatively small such as a range hatched diagonally upward to the right (an angular range of 60° in the circumferential direction at each position in the radial direction).

### Arrangement of Stopper Member

As illustrated in FIG. 6, the stopper member 116 is provided outside the first range Ar1. When assuming that the stopper member 116 is positioned within the first range Ar1, the stopper member 116 might interfere with the bridge section 140b. In this regard, the stopper member 116 in the present embodiment is provided outside the first range Ar1, and thus, interference of the bridge section 140b with the stopper member 116 is suppressed. That is, the present embodiment is considered to be able to enhance the degree of freedom in the layout of the component provided on the base 110, such as the stopper member 116, from the viewpoint that interference between the component and the bridge section 140b can be avoided.

As illustrated in FIG. 6, the stopper member 116 is provided outside a second range Ar2, being a range hatched diagonally downward to the right, in FIG. 6. The second range Ar2 is a part of a region located farther from the pivot axis Ax compared to the outer circumferential surface 120a and closer to the pivot axis Ax compared to the inner circumferential surface 112a. The second range Ar2 is a region aligned in the radial direction with respect to the inner section 140c that is not fixed to the outer circumferential surface 120a or with respect to the outer section 140a that is not fixed to the inner circumferential surface 112a and moves together with the inner circumferential surface 112a. If the stopper member 116 is provided within the second range Ar2, the electrical wire 140 separated from the outer circumferential surface 120a or the inner circumferential surface 112a would interfere with the stopper member 116 when the pivoting unit 120 pivots. In this regard, the stopper member 116 in the present embodiment is provided outside the second range Ar2, and thus, interference of the electrical wire 140 with the stopper member 116 can be avoided.

### Arrangement of Abutting Portion

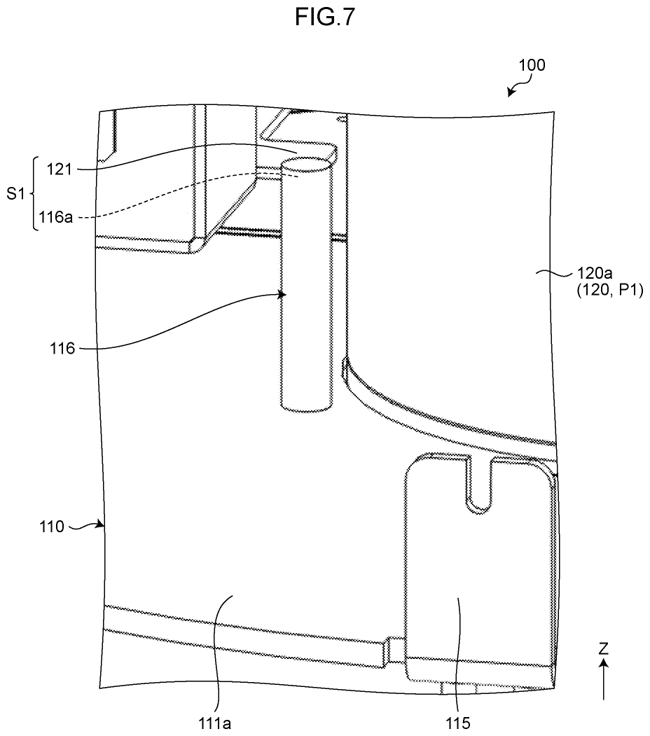

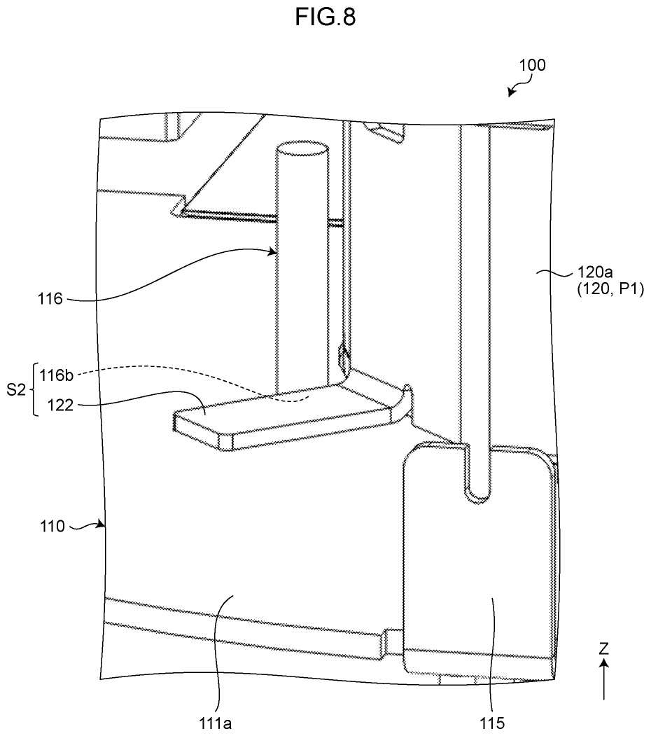

FIG. 7 is a perspective view of a portion including the first stopper mechanism S1 of the transfer machine 100 in the state of FIG. 4. FIG. 8 is a perspective view of a portion including the second stopper mechanism S2 of the transfer machine 100 in the state of FIG. 6.

As illustrated in FIG. 7, the abutting portion 121 is separated upward from the upper surface 111a of the bottom plate 111. Here, as described above, the electrical wire 140 is substantially along the upper surface 111a. That is, the abutting portion 121 and the electrical wire 140 are shifted from each other in the axial direction (Z direction). Therefore, the configuration can suppress interference between the abutting portion 121 and the electrical wire 140 accompanying the pivoting of the pivoting unit 120.

The stopper member 116 has a pillar shape such as a columnar shape extending in the Z direction, for example. This makes it possible to configure the first stopper mechanism S1 at a position separated from the upper surface 111a along which the electrical wire 140 substantially extends.

On the other hand, as illustrated in FIG. 8, the abutting portion 122 is located near the upper surface 111a of the bottom plate 111. However, as illustrated in FIGS. 4 to 6, the abutting portion 122 is provided at a position shifted in the clockwise direction with respect to the fixing position 140fi of the inner section 140c to the pivoting unit 120. The configuration can suppress interference between the abutting portion 122 and a portion of the inner section 140c that is not fixed to the outer circumferential surface 120a accompanying the pivoting of the pivoting unit 120.

Incidentally, the abutting portion 122 may be provided at a position separated from the upper surface 111a in the Z direction. In this case, as illustrated in FIGS. 4 to 6, there may be a guide 117 in the inner section 140c, located at a position closer to the upper surface 111a than (the pivoting trace of) the abutting portion 122, that is, at a position not interfering with the abutting portion 122 in the Z direction. The guide 117 is provided at a position facing the outer circumferential surface 120a with a gap that allows the electrical wire 140 to be placed between the outer circumferential surface 120a and the guide 117, specifically, a gap greater than the diameter of the electrical wire 140. The guide 117 can suppress a large separation of the inner section 140c of the electrical wire 140 from the outer circumferential surface 120a. The guide 117 may be a roller that pivots about a central axis extending substantially in the Z direction. The configuration can reduce the friction when the guide 117 comes into contact with the electrical wire 140, and can suppress hindrance caused by the guide 117 to the movement of the electrical wire 140. The guides 117 may be provided at a plurality of locations at intervals in the circumferential direction. The guide 117 can also be denoted as a separation suppression unit.

As described above, in the present embodiment, the electrical wire 140 that moves accompanying the pivoting of the pivoting unit 120 can be accommodated in a relatively stable shape having the inner section 140c, the outer section 140a, and the bridge section 140b in a limited region between the outer circumferential surface 120a and the inner circumferential surface 112a. The configuration makes it easy to suppress interference of the moving electrical wire 140 with a component, etc. provided on the base 110, leading to suppression of occurrence of an inconvenient event due to the interference, such as hindrance to the pivoting of the pivoting unit 120 or damage to the electrical wire 140.

In addition, in the present embodiment, the electrical wire 140 is preferably fixed to the base 110 (the other of the base and the pivoting unit) at the fixing position 140fo which is an end of the bridge section 140b or the vicinity thereof on the side opposite to the inner section 140c in a state where the length of the outer section 140a is the shortest in the relative pivoting between the base 110 and the pivoting unit 120 (FIG. 6). That is, as illustrated in FIG. 6, when the electrical wire 140 does not include the outer section 140a in this state, the fixing position 140fo is preferably to be an end of the bridge section 140b on the side opposite to the inner section 140c. When the electrical wire 140 has a relatively short outer section 140a (not illustrated) substantially along the inner circumferential surface 112a in the state of FIG. 6, the fixing position 140fo is preferably in the vicinity of the boundary between the outer section 140a and the bridge section 140b. According to this configuration, the length of the outer section 140a, and ultimately, the sum of the lengths of the outer section 140a, the bridge section 140b, and the inner section 140c can be set shorter within the minimum necessary range. This makes it possible to move the electrical wire 140 in a more stable shape in the relative pivoting between the base 110 and the pivoting unit 120.

In addition, in the present embodiment, the electrical wire 140 is preferably fixed to the pivoting unit 120 (one of the base and the pivoting unit) at the fixing position 140fi which is an end of the bridge section 140b or the vicinity thereof on the side opposite to the outer section 140a in a state where the length of the inner section 140c is the shortest in the relative pivoting between the base 110 and the pivoting unit 120 (FIG. 4). That is, as illustrated in FIG. 4, when the electrical wire 140 does not include the inner section 140c in this state, the fixing position 140fi is preferably to be an end of the bridge section 140b on the side opposite to the outer section 140a. In addition, when the electrical wire 140 has a relatively short inner section 140c (not illustrated) substantially along the outer circumferential surface 120a in the state of FIG. 4, the fixing position 140fi is preferably in the vicinity of the boundary between the inner section 140c and the bridge section 140b. According to this configuration, the length of the inner section 140c, and ultimately, the sum of the lengths of the inner section 140c, the bridge section 140b, and the outer section 140a can be set shorter within the minimum necessary range. This makes it possible to move the electrical wire 140 in a more stable shape in the relative pivoting between the base 110 and the pivoting unit 120.

In addition, in the present embodiment, both the abutted portions 116a and 116b are provided in the stopper member 116. According to this configuration, the number of components of the first stopper mechanism S1 and the second stopper mechanism S2 can be reduced compared to a case where the abutted portions 116a and 116b are separately provided, making it possible to obtain an advantage of suppressing manufacturing labor and cost.

In the present embodiment, the stopper member 116 is provided outside the first range Ar1 and the second range Ar2. The configuration makes it possible to suppress interference between the electrical wire 140 that moves accompanying the pivoting of the pivoting unit 120 and the stopper member 116.

In the present embodiment, at least one of the abutting portion 121 and the abutting portion 122 is shifted from the electrical wire 140 in the Z direction. The configuration makes it possible to suppress interference between the electrical wire 140 and at least one of the abutting portion 121 and the abutting portion 122 that move accompanying the pivoting of the pivoting unit 120.

Although the embodiments of the present disclosure have been exemplified as above, the above embodiments are merely examples, and are not intended to limit the scope of the disclosure. The above-described embodiments can be implemented in various other forms, and various omissions, substitutions, combinations, and alterations can be made without departing from the scope and spirit of the disclosure. In addition, it is allowable to implement the embodiments with appropriately modified specifications regarding each configuration, shape, etc. (such as structure, type, direction, model, size, length, width, thickness, height, number, arrangement, position, material).

For example, the inner circumferential surface on the outer side in the radial direction may perform relative pivoting with respect to the outer circumferential surface fixed on the inner side in the radial direction. However, the first range can be set to be narrower in the configuration in which the outer circumferential surface on the inner side in the radial direction performs relative pivoting with respect to the inner circumferential surface fixed on the outer side in the radial direction as described in the above embodiment.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A transfer machine comprising:
a base;
a pivoting unit including a transfer mechanism configured to transfer an article and an electrical component, the pivoting unit being pivotably supported about a pivot axis with respect to the base; and
an electrical wire having a conductive wire electrically connected to the electrical component, the electrical wire being fixed to the base and the pivoting unit,
wherein one of the base and the pivoting unit is provided with an outer circumferential surface extending substantially along a circumferential direction of the pivot axis,
the other of the base and the pivoting unit is provided with an inner circumferential surface extending substantially along the circumferential direction,
the electrical wire includes:
a first section extending substantially along the outer circumferential surface;
a second section extending substantially along the inner circumferential surface; and
a third section that is curved in a state protruding to one side in the circumferential direction between the first section and the second section, and
the third section performs relative movement with respect to the base in the circumferential direction in a first range located farther from the pivot axis compared to the outer circumferential surface and closer to the pivot axis compared to the inner circumferential surface, accompanying the pivoting of the pivoting unit about the pivot axis with respect to the base.

2. The transfer machine according to claim 1, wherein the electrical wire is fixed to the other of the base and the pivoting unit at an end, or in a vicinity of the end, of the third section on a side opposite to the first section in a state where a length of the second section is shortest in relative pivoting between the base and the pivoting unit.

3. The transfer machine according to claim 1, further comprising:
a first stopper mechanism that restricts pivoting of the pivoting unit in a first pivoting direction by abutment between a first abutting portion provided on the pivoting unit and a first abutted portion provided on the base when the pivoting unit pivots about the pivot axis with respect to the base in the first pivoting direction;
a second stopper mechanism that restricts pivoting of the pivoting unit in a second pivoting direction opposite to the first pivoting direction by abutment between a second abutting portion provided on the pivoting unit and a second abutted portion provided on the base when the pivoting unit pivots about the pivot axis with respect to the base in the second pivoting direction; and
a stopper member that is provided on the base and includes the first abutted portion and the second abutted portion.

4. The transfer machine according to claim 3, wherein the stopper member is provided outside the first range.

5. The transfer machine according to claim 3, wherein at least one of the first abutting portion and the second abutting portion is shifted from the electrical wire in an axial direction of the pivot axis.

6. The transfer machine according to claim 4, wherein at least one of the first abutting portion and the second abutting portion is shifted from the electrical wire in an axial direction of the pivot axis.
